(19) United States
(12) Patent Application Publication
(10) Pub. No.: US 2025/0301844 A1
(43) Pub. Date: Sep. 25, 2025

(54) DIRECTIONAL AND MONOCHROMATIC BLUE MICRO-LEDS AND ARTICLES COMPRISING THE SAME

(71) Applicant: University of Virginia Patent Foundation, Charlottesville, VA (US)

(72) Inventor: Kyusang Lee, Crozet, VA (US)

(21) Appl. No.: 19/084,850

(22) Filed: Mar. 20, 2025

Related U.S. Application Data
(60) Provisional application No. 63/567,552, filed on Mar. 20, 2024.

(51) Int. Cl. H10H 29/80; G02B 6/42; G02B 27/01; H10H 20/813; H10H 20/825

(52) U.S. Cl. CPC H10H 29/8421; G02B 6/4206; G02B 27/0172; H10H 20/8131; H10H 29/862; H10H 20/8252

(57) ABSTRACT

In one aspect, the disclosure relates to micro-LED based AR displays combining stacked red, green, and blue LEDs, distributed Bragg reflectors, and diffractive optics; methods of making the same; and augmented reality displays using the same. In one aspect, the light generated by the LEDs is reflected within the optical cavity of DBR/LED/DBR, creating a highly directional (Δθ≤±5°) and monochromatic (FWHM≤5≤nm) blue light. In an aspect, the luminance of the disclosed inorganic-based micro-LEDs is orders of magnitude higher than that of organic LEDs while also providing high directionality and monochromaticity, leading to higher image quality. In a further aspect, the small size of the disclosed light source and combiner allows a much more compact and light-weight AR device to be constructed.

### CROSS-REFERENCE TO RELATED APPLICATIONS

This application claims the benefit of U.S. Provisional Application Ser. No. 63/567,552, filed Mar. 20, 2024, which is incorporated herein by reference in its entirety.

### BACKGROUND

Research on augmented reality (AR) display technology is mainly being carried out by industry. Currently, the most advanced companies and their products include Meta's Oculus Quest, Microsoft's HoloLens, and Apple's Vision Pro, while other companies including Google are also known to be developing such products. These AR devices rely on light sources such as liquid crystal on Si (LCoS), digital light processor, laser beam scanning (LBS), and organic light emitting diode (OLED) on Si (OLEDoS), which are illustrated in FIG. 1. A major limitation of the LCoS, digital light processor, as well as LBS, is the large size and weight of the optics required for reflection/projection, which make devices incorporating these technologies inconvenient and cumbersome to wear. For OLEDoS, low brightness and aspect contrast ratio is a major issue, making the display hard to see clearly on a sunny day, which is a huge problem for the outdoor use of AR products.

Furthermore, AR products require a high pixel density in a compact space, as much as 6-7 times higher than a typical television display, due to the proximity of the wearer's eye. Current technology experiences issues with directionality as well as with color mixing from nearby pixels.

Despite advances in AR display research, there is still a scarcity of micro-LED components that produce high image quality while also being compact in size and light weight. An ideal technology could further avoid color mixing, for example, by having all three colors of light (red, blue, and green) stacked in one pixel instead of existing as separate, adjoining pixels. These needs and other needs are satisfied by the present disclosure.

### SUMMARY

In accordance with the purpose(s) of the present disclosure, as embodied and broadly described herein, the disclosure, in one aspect, relates to micro-LED based AR displays combining freestanding InGaN-based blue LEDs, distributed Bragg reflectors, and diffractive optics; methods of making the same; and augmented reality displays using the same. In one aspect, the light generated by blue LEDs is reflected within the optical cavity of DBR/LED/DBR, creating a highly directional (Δθ≤±5°) and monochromatic (FWHM≤5 nm) blue light. In a further aspect, quantum dots (QDs) can be used to form red and green light via color conversion. In an aspect, the luminance of the disclosed inorganic-based micro-LEDs is orders of magnitude higher than that of organic LEDs while also providing high directionality and monochromaticity, leading to higher image quality. In a further aspect, the small size of the disclosed light source and combiner allows a much more compact and light-weight AR device to be constructed.

This disclosure also relates to collimated beam vertical full-color micro-LEDs for displays. By leveraging remote epitaxy techniques, DBR layers are transferred and bonded between vertically transferred each color LEDs layers, enabling the emission of collimated light for each color. This strategy overcomes the limitations of existing display technologies and achieves high-density monochromaticity to enhance image quality.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 shows schematic illustrations of available light source technologies for AR displays.

FIG. 2 is a conceptual diagram for an AR display based on micro-LEDs and diffractive optical element (DOE) waveguides.

FIG. 3 shows a schematic illustration of the fabrication process of an optical cavity consisting of blue LED membrane sandwiched between two distributed Bragg reflectors (DBRs) via remote epitaxy and two-dimensional material based layer transfer (2DLT). This process integrates the microLEDs with the DBR structure.

FIG. 4 shows an exemplary DBR surrounding a blue-emitting micro LED in accordance with the present disclosure.

FIGS. 5A-5B show a transfer matrix method (TMM) simulation for adjusting thicknesses of TiO₂ and SiO₂ layers in the DBR.

FIG. 6A shows blue light leakage in conventional LEDs coupled with quantum dots FIG. 6B, by contrast, shows monochromatic emission of blue light according to one embodiment of the present disclosure.

FIG. 7 shows a schematic illustration of an optical cavity consisting of vertical full color LED membrane sandwiched between two DBRs via remote epitaxy and 2DLT.

FIG. 8 shows each full color micro-LED is transferred and bonded onto the CMOS backplane, emitting a collimated beam at each pixel.

FIG. 9A shows an example of a Lambertian emission profile for a known microLED with a decreased cell diameter. Designs such as the quantum dot and microLED of FIG. 9 show blue light leakage and a broad FWHM (≥20 nm). FIG. 9B shows an embodiment of a microLED according to the present disclosure with a directional emission profile (Δθ is less than or equal to ±5°) with monochromatic emission (FWHM≤5 nm).

FIG. 10 shows an example optical crosstalk between adjacent pixels in a known display incorporating microLEDs. The close proximity of pixels leads to the crosstalk and affects clarity of the display.

FIGS. 11A-11B show simulation results of directional and monochromatic blue microLEDs based on membranes as disclosed herein.

FIGS. 12A-12F show an exemplary blue membrane-based LED useful in the structures disclosed herein. However, other blue LEDs can also be used with the disclosed DBRs and should be considered disclosed. FIG. 12A: Schematic of the membrane-based LED. FIG. 12B: Electron micrograph of the LED. FIG. 12C: Photograph showing flexibility of the LED. FIGS. 12D-12E: Electrical and optical characterization of the LED, respectively. FIG. 12F: An exemplary array display of multiple blue LEDs.

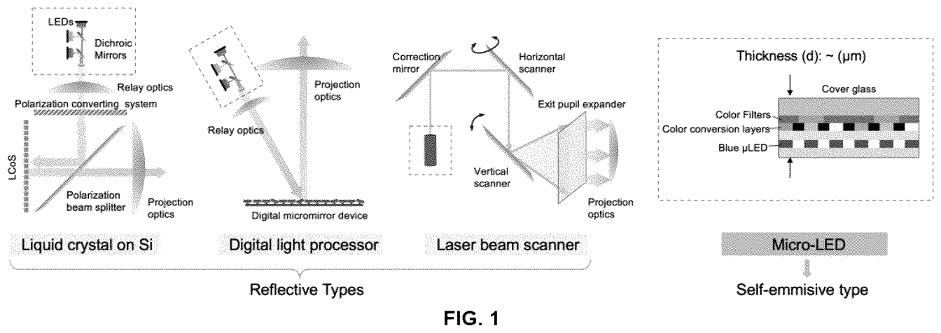

Additional advantages of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### DETAILED DESCRIPTION

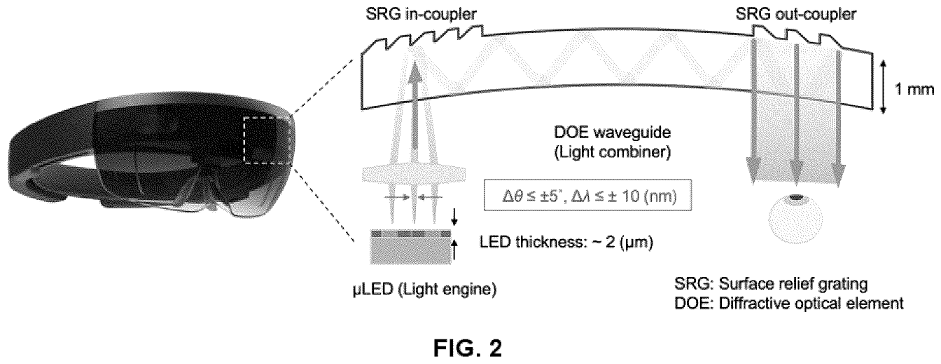

Disclosed herein is a micro-LED-based AR display combining freestanding InGaN-based blue LEDs (obtained via remote epitaxy), distributed Bragg reflectors (DBRs), and diffractive optics, as illustrated in FIG. 2. In one aspect, diffractive optical element (DOE) waveguide and surface relief grating (SRG) in/out-couplers diffract the light emitted by the micro-LEDs onto the lens of AR display.

In one aspect, disclosed herein is a system including at least a substrate; and a plurality of LED units in a vertical stack; wherein each LED unit comprises a base Distributed Bragg Reflector (DBR), a spacer in contact with the base DBR, a top DBR in contact with the spacer; and a colored inorganic LED in contact with the top DBR. In another aspect, the substrate is a mirror. In another aspect, the plurality of LED units comprises three colored inorganic LED units, such as, for example, a red LED unit, a green LED unit, and a blue LED unit. In one aspect, the base DBR of the red LED unit is in contact with the substrate, the base DBR of the green LED unit is in contact with the red LED; and the base DBR of the blue LED unit is in contact with the green LED. In some aspects, the blue LED is a freestanding blue LED membrane produced using an epitaxial growth method such as, for example, remote epitaxy or van der Waals epitaxy, from a III-V semiconductor material. In another aspect, the III-V semiconductor is constructed from at least two of Ga, As, In, P, Al, and N, and optionally includes a dopant selected from Mg, Si, Be, C, or any combination thereof. In one aspect, the III-V semiconductor material is InGaN. In still another aspect, the freestanding blue LED membrane is integrated with the base DBR and the top DBR using 2-dimensional layer transfer (2DLT). In another aspect, the red LED unit and the green LED unit can be quantum dots, can be freestanding LED membranes produced using an epitaxial growth method, or a combination thereof.

In another aspect, each top DBR and each base DBR includes a plurality of pairs of layers comprising a first optical material layer and a second optical material layer. In a further aspect, the plurality of pairs of layers comprises eight pairs of layers. In an aspect, the first optical material layer can be TiO₂.and the second optical material layer comprises SiO₂. However, other optical materials are contemplated and should be considered disclosed. Useful optical materials are discussed in more detail below.

In one aspect, each first optical material layer has a thickness of from about 30 nm to about 45 nm or of about 38 nm and each second optical material layer has a thickness of from about 65 nm to about 80 nm or of about 73 nm when the optical materials are TiO₂ and SiO₂, respectively. In another aspect, the first optical material layer can be or include TiO₂, Ta₂O₅, HfO₂, Nb₂O₅, MgF₂, or any combination thereof. In one aspect, the second optical material layer can be SiO₂, ZnS, Al₂O₃, or any combination thereof.

In one aspect, additional possible combinations of second and first optical material layers, respectively, include SiO₂/TiO₂, SiO₂/Ta₂O₅, SiO₂/HfO₂, SiO₂/Nb₂O₅, ZnS/MgF₂, and Al₂O₃/TiO₂.

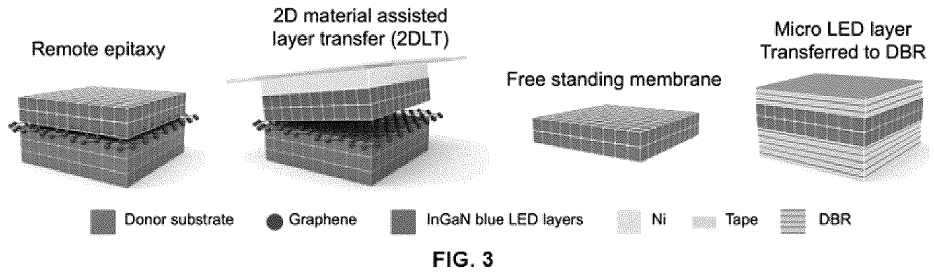

In an aspect, the disclosed systems are in contact with a complementary metal-oxide-silicon (CMOS) backplane. In another aspect, the light generated by blue LEDs is reflected within the optical cavity of DBR/LED/DBR, creating a highly directional (Δθ≤±5°) and monochromatic (FWHM≤5 nm) blue light, which is illustrated in the schematic illustration in FIG. 3. In a further aspect, quantum dots (QDs) can be used to form red and green light via color conversion. In any of these aspects, DBR structures can enhance directional emission and color purity with increasing electroluminescent intensity (EL) compared to LEDs based on other architectures.

In one aspect, the DBRs disclosed herein can be made from 4 sets of alternating layers of two materials such as, for example, TiO₂ and SiO₂, where TiO₂ is a base layer and SiO₂ is a top layer. In an aspect, the thickness of TiO₂ layers can be about 37.8 nm for a blue LED, while the thickness of an SiO₂ layer can be about 78.3 nm for a blue LED. Other dielectric substances can also be used to produce the DBRs and should be considered disclosed. These include, but are not limited to, aluminum oxide (Al₂O₃), silicon nitride (Si₃N₄), zirconium dioxide (ZrO₂), magnesium fluoride (MgF₂), hafnium oxide (HfO₂), combinations thereof, and the like. In an aspect, the thicknesses of the layers can vary from about 10 nm to about 1000 nm, or from about 25 nm to about 500 nm, or from about 35 nm to about 100 nm, or a combination of any of the foregoing values. In an aspect, thicknesses of the layers can be varied based on the particular materials used for the layers and their refractive indices as well as the desired wavelengths to be accommodated.

In some aspects, for wavelengths other than blue (e.g. in the red and green range), thickness range of the DBR layers can be from about 10 nm to about 10 μm, from about 50 nm to about 5 μm, from about 100 nm to about 500 nm, or a combination of any of the foregoing values. In one aspect, varying thickness within a broad range allows for customization of the LED structure to satisfy diverse optical requirements and to improve the efficiency and color purity of LEDs for specific applications.

In an aspect, the luminance of the disclosed inorganic-based micro-LEDs is orders of magnitude higher than that of OLEDs, offering potential to solve the visibility issue. In a further aspect, an advantage of the disclosed approach is that it can provide much higher directionality and monochromaticity, which will lead to higher image quality, compared to current technologies. In a further aspect, the small size of the disclosed light source and combiner allows a much more compact and light-weight AR device to be constructed.

This disclosure offers significant advancements in AR display technology by providing a compact, lightweight, and high-brightness solution. In one aspect, by leveraging remote epitaxy and DBR integration, the disclosed device achieves superior performance in terms of directionality and monochromaticity, thereby enhancing user experience and usability.

In an aspect, disclosed herein is a novel approach to AR display technology utilizing directional and monochromatic micro-LEDs. In a further aspect, the use of remote epitaxy to integrate full color vertical transferred LED membranes between distributed Bragg reflector (DBR) layers, results in a device capable of emitting strong light with high directionality and monochromaticity. In another aspect, the disclosed devices address the limitations of existing AR display technologies and significantly improving image quality and device compactness, thus advancing the field of augmented reality.

### Epitaxial Growth Methods

In one aspect, remote epitaxy or van der Waals epitaxy can be used to produce inorganic blue LEDs useful in the disclosed AR displays. In a further aspect, in remote epitaxy, a substrate wafer is coated with a layer of graphene or similar substance. Atoms are deposited on the graphene covered substrate, arranging in a crystalline pattern according to the pattern of the underlying wafer. However, in one aspect, LEDs grown by epitaxial growth methods can be removed from the substrate following formation due to the intervening layer of graphene (as in remote epitaxy) or due to the lack of interlayer covalent bonding (as in van der Waals epitaxy). In one aspect, LEDs and other components grown using epitaxial growth methods can be flexible and/or freestanding, or can be surrounded by other components, such as, for example, the DBRs described herein.

### Distributed Bragg Reflectors

In one aspect, when distributed Bragg reflectors (DBRs) are used in conjunction with LEDs, DBRs can enhance directional emission, spectral narrowing, and color purity, even at increasing intensity. In order to achieve these improved properties, micro LEDs must be integrated with the DBR structure. In one aspect, two-dimensional material based layer transfer (2DLT) can be used following remote epitaxy in order to apply a free-standing micro LED to one or more DBRs.

In one aspect, the following equation can be useful when considering DBR interaction with LEDs:

$${T}_{l , h} = {λ}_{l , h} / 4 = {λ}_{0} / 4 {n}_{l , h}$$

where l,h represents vacuum Bragg Wavelengths of light, T_{l,h} represents thickness of the low and high refractive index material, and n_{l,h} represents refractive indices of the low and high materials. In one aspect, in the case of vertical incidence, the thickness of each layer becomes 1/4 of a wavelength and alternately use nₕ and nₗ having a large and small refractive index. In another aspect, the multi-layer thin film DBR can make light reflected and all reflected light make constructive interference.

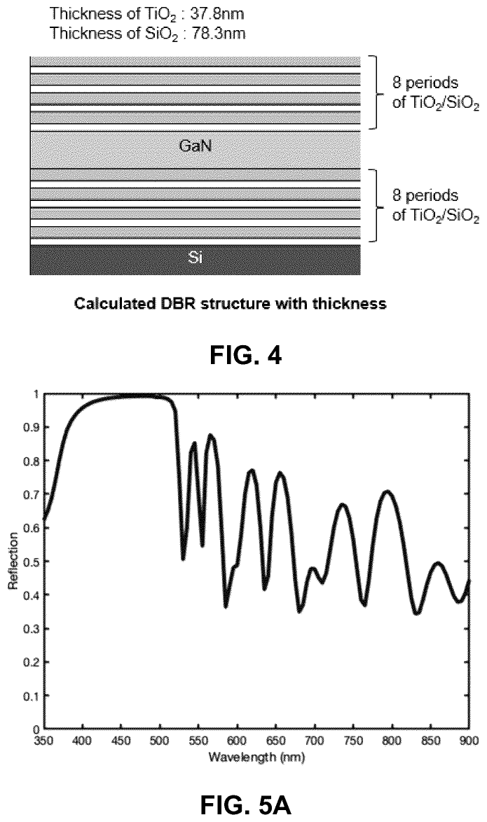

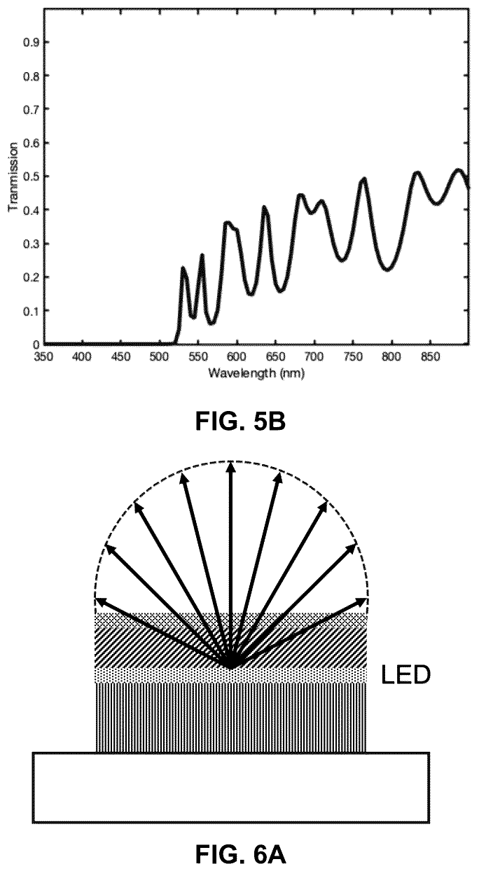

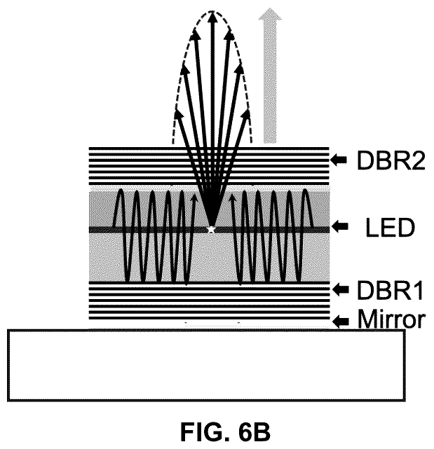

The refractive index of TiO₂ is about 3.1041, while the refractive index of SiO₂ is about 1.5. In one aspect, to achieve effective reflection from DBR structures, SiO₂ and TiO₂ can be employed with 8 pairs for both bottom and top DBR layers. In another aspect, for DBR layers, TiO₂ layer is deposited on a Si substrate and SiO₂ is deposited on the TiO₂ layer. In still another aspect, the calculated thicknesses of TiO₂ and SiO₂ are 37.85 nm and 78.3 nm, respectively (see FIG. 4).

In another aspect, other numbers of layers can vary based on the particular optical requirements in a given situation. In an aspect, although 8 pairs of layers is optimized for a central wavelength (e.g. for a blue LED), a varied number of layers is contemplated and should be considered disclosed for different central wavelengths. In an aspect, and without wishing to be bound by theory, the optimal number of layers can be varied to match different wavelengths and specific application needs, allowing for flexibility in design to achieve targeted optical properties. Number of layers can also vary depending on the dielectric materials used to construct the layers.

In one aspect, the thicknesses of TiO₂ and SiO₂ are adjusted from the calculated thicknesses using the central wavelength and refractive index of each layer. In a further aspect, with 25 nm of TiO₂ and 85 nm of SiO₂, reflection of approximately 100% across the blue wavelength range can be calculated. In a similar aspect, thicknesses of other dielectric materials including aluminum oxide (Al₂O₃), silicon nitride (Si₃N₄), zirconium dioxide (ZrO₂), magnesium fluoride (MgF₂), hafnium oxide (HfO₂), combinations thereof, and the like, can be similarly calculated and adjusted.

### Blue Light Leakage

In an aspect, conventional designs involving micro LEDs and quantum dots (QDs) lead to blue light leakage and a broad FWHM of 20 nm. However, in the present case, where micro LEDs are used in conjunction with DBRs, the directional profile is such that Δθ≤5°, while monochromatic emission is achieved (FWHM s 5 nm), thus addressing the problem of blue light leakage.

### Membrane Based Displays

In an aspect, the disclosed membrane-based LED displays offer improvements in performance relative to current technology. In another aspect, to achieve the desired narrow beam profile and FWHM, overall LED thickness must be reduced. In still another aspect, it has been discovered that eight pairs of DBR for both the top and bottom sides of the micro LED is sufficient for beam collimation, leading to significant improvements in color purity.

Many modifications and other embodiments disclosed herein will come to mind to one skilled in the art to which the disclosed compositions and methods pertain having the benefit of the teachings presented in the foregoing descriptions and the associated drawings. Therefore, it is to be understood that the disclosures are not to be limited to the specific embodiments disclosed and that modifications and other embodiments are intended to be included within the scope of the appended claims. The skilled artisan will recognize many variants and adaptations of the aspects described herein. These variants and adaptations are intended to be included in the teachings of this disclosure and to be encompassed by the claims herein.

Although specific terms are employed herein, they are used in a generic and descriptive sense only and not for purposes of limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, the dates of publication provided herein can be different from the actual publication dates, which can require independent confirmation.

While aspects of the present disclosure can be described and claimed in a particular statutory class, such as the system statutory class, this is for convenience only and one of skill in the art will understand that each aspect of the present disclosure can be described and claimed in any statutory class.

It is also to be understood that the terminology used herein is for the purpose of describing particular aspects only and is not intended to be limiting. Unless defined otherwise, all technical and scientific terms used herein have the same meaning as commonly understood by one of ordinary skill in the art to which the disclosed compositions and methods belong. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

Prior to describing the various aspects of the present disclosure, the following definitions are provided and should be used unless otherwise indicated. Additional terms may be defined elsewhere in the present disclosure.

### Definitions

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by”, “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.”

As used in the specification and the appended claims, the singular forms “a,” “an” and “the” include plural referents unless the context clearly dictates otherwise. Thus, for example, reference to “a distributed Bragg reflector,” “a pixel,” or “an LED,” include, but are not limited to, mixtures, combinations, or series of two or more such distributed Bragg reflectors, pixels, or LEDs, and the like.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y’, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y’, and ‘greater than z’. In addition, the phrase “about ‘x’ to ‘y’”, where ‘x’ and ‘y’ are numerical values, includes “about ‘x’ to about ‘y’”.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

As used herein, the terms “optional” or “optionally” means that the subsequently described event or circumstance can or cannot occur, and that the description includes instances where said event or circumstance occurs and instances where it does not.

As used herein, “remote epitaxy” refers to a process by which a crystalline material such as, for example, a semiconductor is grown on a substrate, wherein the substrate or a coating or additional layer on the substrate allows for easy layer release from the substrate without damaging the material grown by remote epitaxy. In an aspect, an intervening layer can be made of a material such as, for example, graphene or boron nitride, or any layer that will adhere to the substrate while having only weak van der Waals interactions with the crystalline material, thereby facilitating release of the crystalline material. In some aspects, graphene-coated substrates can be reused, offering cost savings. In another aspect, films and crystalline materials grown using remote epitaxy perform as well as conventionally prepared films. In still another aspect, the process of remote epitaxy is fast. In one aspect, in remote epitaxy, graphene or boron nitride and the like cannot completely screen or block the potential field of the substrate, thus allowing epitaxial growth to occur despite the presence of the intervening layer (e.g. graphene or boron nitride). In still another aspect, morphological features of materials grown by remote epitaxy can be transferred from the substrate despite the presence of the intervening layer and the fragility of the single crystalline layers produced by remote epitaxy. In some aspects, use of remote epitaxy overcomes previously known limitations of III-V semiconductors including, but not limited to, transfer to arbitrary substrates, thermal management, and the like. In still another aspect, materials produced by remote epitaxy, including but not limited to LED membranes, are thinner than alternatives such as, for example, quantum dots, allowing for improved optical properties in devices constructed therefrom. In another aspect, these advantages may be especially important for blue LEDs. In still another aspect, materials produced by remote epitaxy can be easily stacked, facilitating their integration into other devices, and allowing coupling of bulk 3D materials through 2D interfaces produced by remote epitaxy. In yet another aspect, the technique of remote epitaxy allows for growth of numerous materials and is thus less limited and more universal than other fabrication techniques. In still another aspect, remote epitaxy allows for precise thickness control of freestanding membranes.

As used herein, “van der Waals epitaxy” or “vdW epitaxy” refers to epitaxial growth method for two-dimensional materials. In one aspect, in vdW epitaxy, the growing layer is held together with the substrate by a weak van der Waals interaction. In a further aspect, in this method, there is no out-of-plane covalent bonding between the growing material and the substrate, thus facilitating removal and/or transfer of the 2D material following fabrication. In still another aspect, vdW epitaxy can be grown on both polar and non-polar substrates. In some aspects, vdW epitaxy substrates can be reused several times without cleaning or polishing while still producing defect-free films. In a further aspect, reuse and easy transfer of the 2D materials as in vdW epitaxy lead to reduce production costs of membranes made therefrom.

“Two dimensional layer transfer” or “2DLT” as used herein refers to a method by which a fragile, two-dimensional material such as, for example, a single crystalline layer or blue LED membrane produced by remote epitaxy as described herein, can be transferred to a substrate for use in an electronic device, optical device, or the like. In an aspect, 2DLT techniques allow transfer of fragile materials to other device layers (e.g. DBRs) without damage. In still another aspect, 2DLT techniques allow separate fabrication of 2D materials rather than sequential, layer-by-layer construction of devices, thus allowing further customization of electronic and optical components. In yet another aspect, 2DLT allows fabrication to proceed without using glues or high temperature bonding. Further in this aspect, van der Waals interactions can provide the necessary physical integration for 2DLT processes. In another aspect, remote epitaxy coupled with 2DLT allows the 2D material to remain clean, thus enabling better performance due to lack of defects, contamination, or the like. In one aspect, 2DLT can be accomplished using mechanical or adhesive forces (e.g. tape) to pick up and transfer the 2D material to another component such as a DBR, due to weak physical bonds between the substrate and the membrane being grown..

Unless otherwise specified, temperatures referred to herein are based on atmospheric pressure (i.e. one atmosphere).

Now having described the aspects of the present disclosure, in general, the following Examples describe some additional aspects of the present disclosure. While aspects of the present disclosure are described in connection with the following examples and the corresponding text and figures, there is no intent to limit aspects of the present disclosure to this description. On the contrary, the intent is to cover all alternatives, modifications, and equivalents included within the spirit and scope of the present disclosure.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the disclosure and are not intended to limit the scope of what the inventors regard as their disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### Example 1: Fabrication of Blue Micro-LEDs

Blue LED membranes were produced by conducting remote epitaxy on III-N wafers coated with mono- or bilayer of 2D materials such as graphene (Gr) or boron nitride (BN), which allowed the LEDs to be peeled off from wafers due to weak van der Waals interface. The DBR was separately simulated, designed, fabricated, and tested. In some experiments, 2D materials were directly grown on wafers. In other experiments, single-crystal thin films were grown on the substrates coated with 2D materials. In still other experiments, heterostructures for blue LEDs were developed. In some cases, III-V growth can be used. III-V materials include Ga, As, In, P, and Al as the main sources with Mg, Si, Be, and C as doping sources. III-N materials include Ga, In, Al, and N₂ plasma as main sources with Mg, Si, Fe, and C as doping sources. An ultra-high vacuum molecular beam epitaxy (MBE) system can produce single crystal GaN as well as combinations of III-V and III-N materials without breaking the vacuum. Reflection high-energy diffraction (RHEED) can be used for in situ monitoring of crystallinity. Most standard Si, Ge, SiGe, and III-V can be obtained with a variety of dopants in this system. Available gas sources include germane, silane, phosphine, arsine, and diborane. Available metal-organic sources include trimethyl antimony, dimethyl zinc, trimethyl indium, bromo trichloro methane, trimethyl aluminum, trimethyl gallium, and diethyl telluride.

An ultra-high vacuum chemical vapor deposition (UHV CVD) system is used for growing epitaxial graphene, which is used to enable exfoliation of device layers in remote epitaxy. This system can also reach temperatures up to 2000 K to graphitize SiC substrates forming 4-inch wafer-scale single-crystalline graphene on top of a SiC surface. Gas sources for this system include GeH₄/SiH₄, C₃He/CH₄, N₂, H₂, and Ar and can be used to grow Ge, Si, SiC, and diamond films. A low (<100 fA) leakage current probe station is used for electrical transport measurement in fabricated electronic devices such as micro-LEDs.

A multi-function physical vapor deposition (PVD) system from RMV that includes both DC/RF magnetron sputtering and E-beam evaporation tools is equipped with mass flow controller (MFC) for three different gases, an E-beam stage which includes the rotatable pockets for 4 different sources, and sputtering guns for two different 3-inch targets. This multi-functional system allows deposition of high stress metal layer for 2DLT process. An ex-situ Photoluminescence (PL) Measurement System, comprised of a 532 nm laser, a Horiba iHR320 imaging spectrometer, and high-performance photodiodes from Electro-Optical Systems including Si, PbSe, and InGaAs with a spectral range of 150 to 1500 nm with a grating of 1200 g/mm and a wavelength accuracy of ±0.20 nm can be used to characterize the quality of epitaxial layer for the LED in this project. A wafer bonder system (Karl SUSS XB8-Wafer bonder) for precisely joining two wafers (or sections of a wafer) together can also be used herein. The XB8 wafer bonder offers an extremely large parameter window, including bond force options of 60 kN and 100 kN and a temperature range of up to 550° C. Ramp functions also enable the process to be adapted optimally to special bonding requirements. Different substrate forms and wafer sizes are processed in specially adapted fixtures.

The DBR was then integrated on the bottom surface of an LED by either: (i) transferring LED film on fabricated DBR via oxide-oxide bonding or by using a transparent polymer adhesion layer, or (ii) fabricating DBR at low temperature on the bottom surface of exfoliated LED film on thermal-release tape followed by transfer on substrate. Another DBR was then formed on top of the transferred LED. A 3×3 array of micro-LEDs was fabricated using dry etching techniques for mesa formation and patterned lift-off for metallization. The fabricated micro-LEDs were characterized for I-V characteristic, external quantum efficiency (EQE), and luminance, as well as for radiation pattern and FWHM. In some experiments, active layer thickness and DBR thickness were designed and optimized using simulations.

Vertical integration of LEDs with DBR was achieved in two different ways. In the first way, LEDs were transferred on DBR via oxide-oxide bonding or a transparent polymer adhesive layer.

In the second way, DBRs were fabricated at low temperature on exfoliated LED membranes on tape.

LED illumination angle of <10 degrees (90% light), and (2) achieving full width at half maximum (FWHM) of <5 nm can be achieved.

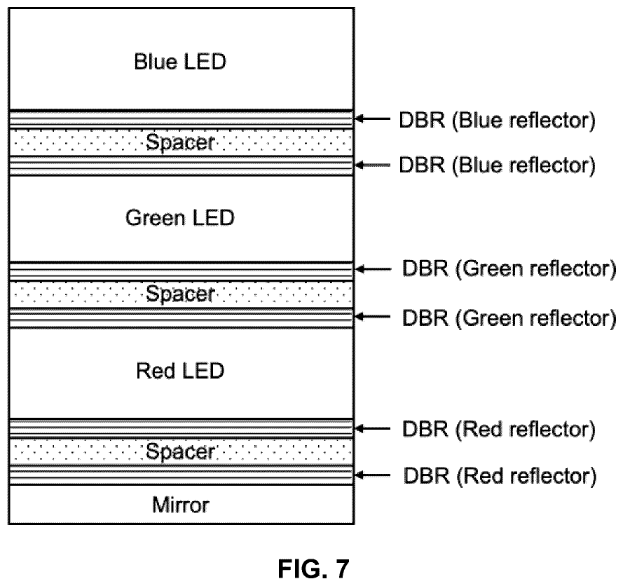

Similar techniques can be used to fabricate green and red micro LEDs. In some cases, green and/or red quantum dots (QDs) can be used, but in other cases, green and/or red micro LEDs produced by remote epitaxy can be used in vertical stacks with the blue micro LEDs as demonstrated in FIG. 7 and Example 2.

### Example 2: Construction of Optical Cavity Having a Vertical Full-Color LED Membrane

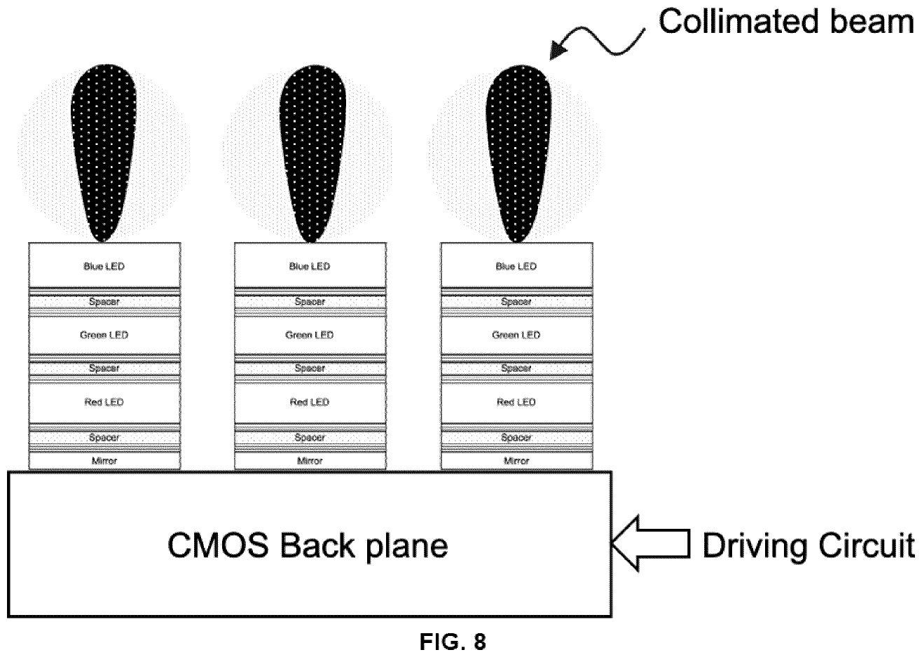

Each color of LED membranes is produced using remote epitaxy techniques on III-N or III-V wafers coated with 2D materials such as graphene or boron nitride. Subsequently, DBR design, fabrication, and testing are conducted to ensure proper beam collimation. Integration of DBR layers with LED membranes is achieved through methods such as oxide-oxide bonding or transparent polymer adhesion, followed by micro-LED array fabrication and characterization. The LED membrane, as depicted in FIG. 7, consists of distributed Bragg reflector (DBR) layers and spacers between each LED membrane, with a reflector at the bottom. Colors for each layer, from bottom to top, are stacked in the order of red, green, and blue to suppress color interference during emission. This configuration generates strong blue light while maintaining high directionality and monochromaticity. Additionally, as shown in FIG. 8, each pixel is transferred onto a CMOS backplane, enabling the creation of a display driven by a collimated beam at each pixel. Such design enhances the performance of AR/VR displays.

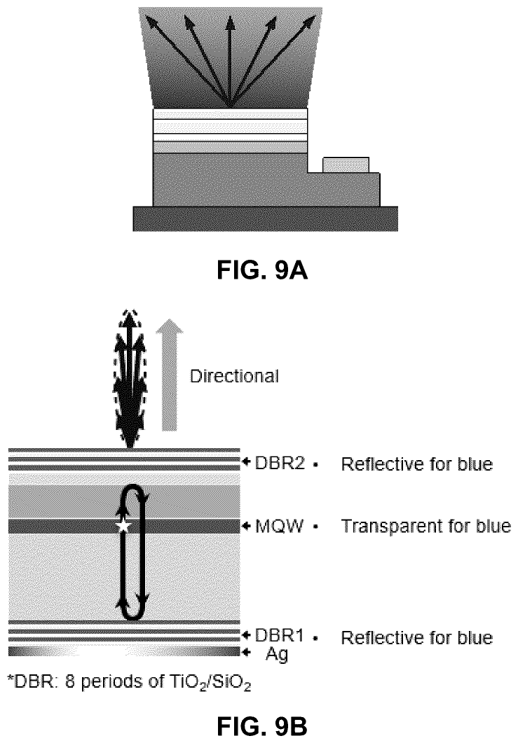

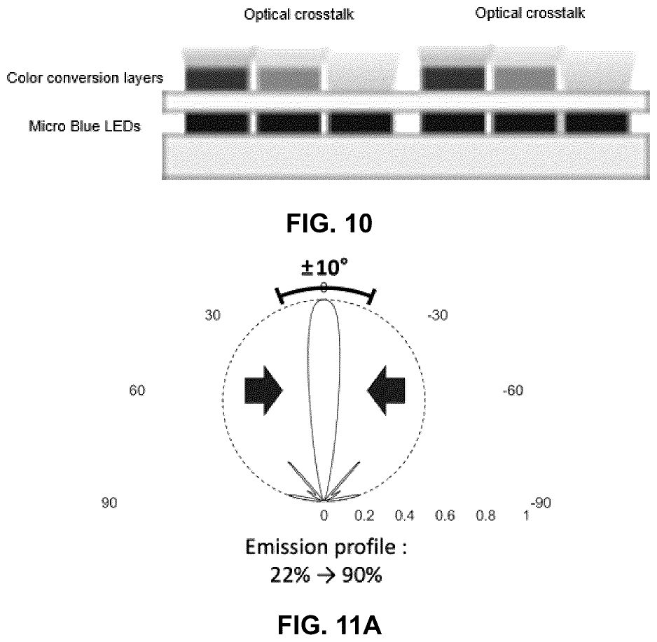

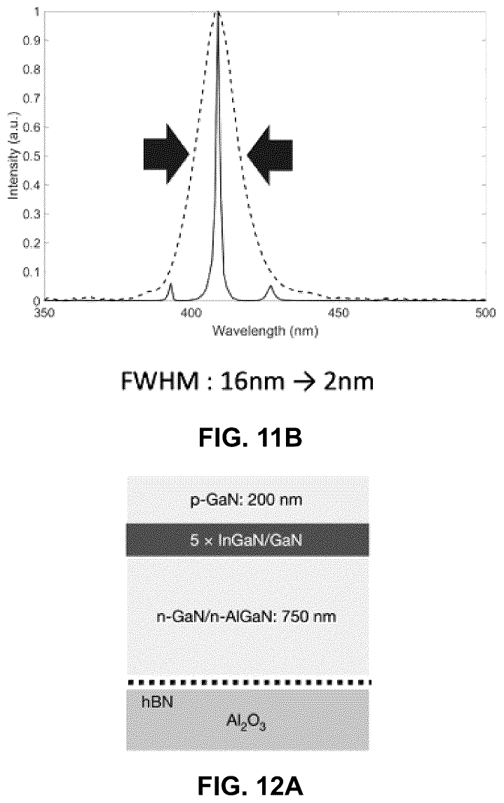

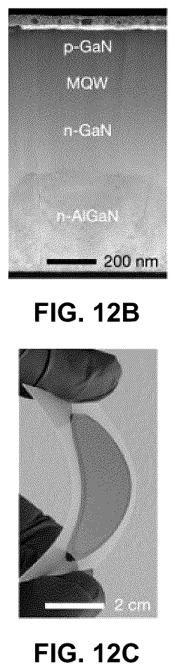

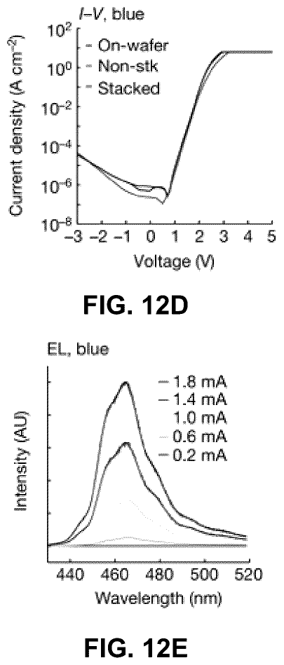

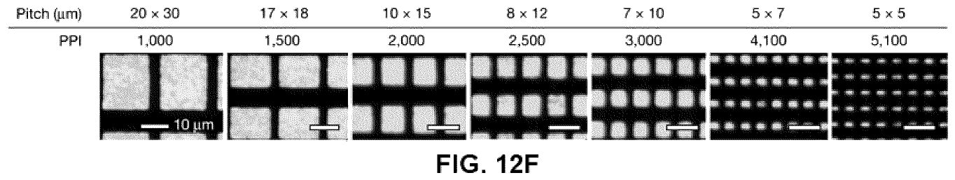

Layering of the membrane based LED (see FIG. 9B) is described in Table 1. Layering of the DBR structures (see FIG. 9B) is described in Table 2.

TABLE 1
Exemplary LED Structure

| Component | Height (nm) |
|---|---|
| p++ contact | 30 |
| p-GaN | 100 |
| GaN/InGaN MQW | 100 |
| n-GaN | 300 |
| GaN buffer layer | 300 |

TABLE 2
Exemplary DBR 1 and 2 Structures

| Layer | Height (nm) |
|---|---|
| TiO₂ | 38 |
| SiO₂ | 73 |
| TiO₂ | 38 |
| SiO₂ | 73 |
| TiO₂ | 38 |
| SiO₂ | 73 |
| TiO₂ | 38 |
| SiO₂ | 73 |
| TiO₂ | 38 |
| SiO₂ | 73 |
| TiO₂ | 38 |
| SiO₂ | 73 |
| TiO₂ | 38 |
| SiO₂ | 73 |
| TiO₂ | 38 |
| SiO₂ | 73 |

As shown, membrane-based LEDs show superior performance for micro-display pixels towards AR applications. To achieve the expected performance of narrow beam profile and FWHM, the overall LED thickness must be reduced. It has been found that 8 pairs of DBR for both the top and bottom sides of microLEDs is sufficient for beam collimation. Simulations show dramatic improvement in both beam collimation and color purity.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

What is claimed is:

1. A system comprising:
a substrate; and
a plurality of LED units in a vertical stack; wherein at least one LED unit of the plurality is a blue LED unit;
wherein each LED unit comprises a base Distributed Bragg Reflector (DBR), a spacer in contact with the base DBR, a top DBR in contact with the spacer; and a colored inorganic LED in contact with the top DBR;
wherein the blue LED comprises a freestanding blue LED membrane produced using an epitaxial growth method from a III-V-semiconductor material.

2. The method of claim 1, wherein the epitaxial growth method comprises remote epitaxy or van der Waals epitaxy.

3. The system of claim 1, wherein the III-V semiconductor material comprises at least two of Ga, As, In, P, Al, and N, optionally with a dopant selected from Mg, Si, Be, C, or a combination thereof.

4. The system of claim 1, wherein the III-V-semiconductor material comprises InGaN.

5. The system of claim 1, wherein the freestanding blue LED membrane is integrated with the base DBR and the top DBR using 2-dimensional layer transfer (2DLT).

6. The system of claim 1, wherein the substrate is a mirror.

7. The system of claim 1, wherein the plurality of LED units comprises further comprises a red LED unit and a green LED unit.

8. The system of claim 7, wherein the red LED unit and the green LED unit comprise quantum dots or freestanding LED membranes produced using an epitaxial growth method.

9. The system of claim 7, wherein the base DBR of the red LED unit is in contact with the substrate, wherein the base DBR of the green LED unit is in contact with the red LED; and wherein the base DBR of the blue LED unit is in contact with the green LED.

10. The system of claim 1, wherein each top DBR and each base DBR comprises a plurality of pairs of layers comprising a first optical material layer and a second optical material layer.

11. The system of claim 10, wherein the plurality of pairs of layers comprises eight pairs of layers.

12. The system of claim 10, wherein the first optical material layer comprises TiO₂, Ta₂O₅, HfO₂, Nb₂O₅, MgF₂, or any combination thereof.

13. The system of claim 10, wherein the second optical material layer comprises SiO₂, ZnS, Al₂O₃, or any combination thereof.

14. The system of claim 10, wherein the first optical material layer comprises TiO₂ and the second optical material layer comprises SiO₂.

15. The system of claim 10, wherein each first optical material layer has a thickness of from about 30 nm to about 45 nm and wherein each second optical material layer has a thickness of from about 65 nm to about 80 nm.

16. The system of claim 1, wherein the system comprises a directional profile for blue light with Δθ of ±5°.

17. The system of claim 1, wherein monochromatic blue emission has a full width at half maximum of less than or equal to 5 nm.

18. An augmented reality (AR) display comprising a plurality of systems according to claim 1, further comprising a diffractive optical element (DOE) waveguide and surface relief grating (SRG) couplers.

19. The AR display of claim 18, wherein the DOE waveguide and SRG couplers diffract light emitted by the plurality of LEDs to a lens of the AR display.

20. The AR display of claim 18, wherein the plurality of systems are in contact with a complementary metal-oxide-silicon (CMOS) backplane.
